(19) United States
(12) Patent Application Publication
(10) Pub. No.: US 2025/0392863 A1
(43) Pub. Date: Dec. 25, 2025

(54) METHODS AND APPARATUS TO STRUCTURE AUDIO AMPLIFIERS FOR ULTRASONIC SIGNAL GENERATION

(71) Applicant: Texas Instruments Incorporated, Dallas, TX (US)

(72) Inventors: Jasjot Singh Chadha, Allen, TX (US); Sree Nilendra Gadre, Hyderabad (IN); Mukul Ratwani, Ajmer (IN)

(21) Appl. No.: 18/932,847

(22) Filed: Oct. 31, 2024

Related U.S. Application Data
(60) Provisional application No. 63/662,010, filed on Jun. 20, 2024.

(51) Int. Cl. H04R 3/04; G06F 3/16; H03F 3/183

(52) U.S. Cl. CPC H04R 3/04; G06F 3/162; H03F 3/183; H03F 2200/03; H04R 2430/01

(57) ABSTRACT

An example apparatus includes: audio amplifier circuitry including: audio signal processing circuitry having an output; a register having an output; ultrasonic chirp generator circuitry having an input and an output, the input of the ultrasonic chirp generator circuitry coupled to the output of the register; combination circuitry having a first input, a second input, and an output, the first input of the combination circuitry coupled to the output of the audio signal processing circuitry, the second input of the combination circuitry coupled to the ultrasonic chirp generator circuitry; digital-to-analog converter (DAC) circuitry having an input and an output, the input of the DAC circuitry coupled to the output of the combination circuitry; and an amplifier having an input coupled to the output of the DAC circuitry.

### CROSS REFERENCE TO RELATED APPLICATION

This patent application claims the benefit of and priority to U.S. Provisional Patent Application No. 63/662,010 filed Jun. 20, 2024, which is hereby incorporated herein by reference in its entirety.

### TECHNICAL FIELD

This description relates generally to audio amplifiers and, more particularly, to methods and apparatus to structure audio amplifiers for ultrasonic signal generation.

### BACKGROUND

Audio systems utilize audio amplifier circuitry to convert digital audio data into continuous analog audio signals. Some audio amplifier circuitry also includes circuitry to perform one or more additional operations on the digital audio data prior to producing the analog audio signals. Such circuitry allows audio amplifier circuitry to support an increasing number of audio operations.

### SUMMARY

For methods and apparatus to structure audio amplifiers for ultrasonic signal generation, an example apparatus includes an audio amplifier circuitry including: audio signal processing circuitry having an output; a register having an output; ultrasonic chirp generator circuitry having an input and an output, the input of the ultrasonic chirp generator circuitry coupled to the output of the register; combination circuitry having a first input, a second input, and an output, the first input of the combination circuitry coupled to the output of the audio signal processing circuitry, the second input of the combination circuitry coupled to the ultrasonic chirp generator circuitry; digital-to-analog converter (DAC) circuitry having an input and an output, the input of the DAC circuitry coupled to the output of the combination circuitry; and an amplifier having an input coupled to the output of the DAC circuitry. Other examples are described.

For methods and apparatus to structure audio amplifiers for ultrasonic signal generation, an example apparatus includes programmable circuitry having an output; audio amplifier circuitry including: audio signal processing circuitry having an input and an output, the input of the audio signal processing circuitry coupled to the output of the programmable circuitry; ultrasonic chirp generator circuitry having an output; combination circuitry having a first input, a second input, and an output, the first input of the combination circuitry coupled to the output of the audio signal processing circuitry, the second input of the combination circuitry coupled to the output of the ultrasonic chirp generator circuitry; and an audio channel having an input and an output, the input of the audio channel coupled to the output of the combination circuitry; and a speaker having an input coupled to the output of the audio channel. Other examples are described.

For methods and apparatus to structure audio amplifiers for ultrasonic signal generation, an example apparatus includes an audio amplifier circuitry including: audio signal processing circuitry having an output; ultrasonic chirp generator circuitry having an output, the ultrasonic chirp generator circuitry configured to generate an ultrasonic chirp signal having a plurality of frequencies, the plurality of frequencies are based on a start frequency, a step frequency, and an amplitude; combination circuitry having a first input, a second input, and an output, the first input of the combination circuitry coupled to the output of the audio signal processing circuitry, the second input of the combination circuitry coupled to the ultrasonic chirp generator circuitry, the combination circuitry configured to combine an audible audio signal and the ultrasonic chirp signal; and an audio channel having an input coupled to the output of the combination circuitry. Other examples are described.

### BRIEF DESCRIPTION OF THE DRAWINGS

FIG. 1 is a block diagram of an example audio system including example audio amplifier circuitry.

FIG. 2 is a block diagram of an example of the audio amplifier circuitry of FIG. 1 including example ultrasonic chirp generator circuitry.

FIG. 3 is a timing diagram of example operations of the ultrasonic chirp generator circuitry of FIG. 2, or more generally the audio amplifier circuitry of FIGS. 1 and 2.

FIG. 4 is a timing diagram of example operations of the ultrasonic chirp generator circuitry of FIG. 2, or more generally the audio amplifier circuitry of FIGS. 1 and 2.

FIG. 5 is a flowchart representative of example machine-readable instructions or example operations that may be at least one of executed, instantiated, or performed using an example implementation of the audio amplifier circuitry of FIGS. 1 and 2.

FIG. 6 is a block diagram of an example processing platform including programmable circuitry structured to execute, instantiate, or perform the example machine-readable instructions or perform the example operations of FIGS. 3, 4, and 5 to implement the audio amplifier circuitry of FIGS. 1 and 2.

FIG. 7 is a block diagram of an example implementation of the programmable circuitry of FIG. 6.

FIG. 8 is a block diagram of another example implementation of the programmable circuitry of FIG. 6.

The drawings are not necessarily to scale. Generally, the same reference numbers in the drawing(s) and this description refer to the same or similar (functionally and/or structurally) features and/or parts. Although the drawings show regions with clean lines and boundaries, some or all of these lines and boundaries may be idealized. In reality, the boundaries or lines may be unobservable, blended or irregular.

### DETAILED DESCRIPTION

Audio systems utilize audio amplifier circuitry to convert digital audio data into continuous analog audio signals. Some audio amplifier circuitry also includes circuitry to perform one or more additional operations on the digital audio data prior to producing the analog audio signals. Such circuitry allows audio amplifier circuitry to support an increasing number of audio operations.

Audio systems often include programmable circuitry, audio amplifier circuitry, a speaker, and a microphone. The programmable circuitry is structured as an audio source, which supplies a digital audio signal. The audio amplifier circuitry produces an analog audio signal by converting the digital audio signal. The audio amplifier circuitry may include circuitry to amplify the audio signal or condition the audio signal to improve audio quality. The audio amplifier circuitry further provides a reference echo signal to the programmable circuitry, which represents the conditioned audio signal. The programmable circuitry uses the echo reference signal to remove the audible portions of the audio signal from signals received by the microphone. Such operations prevent reverberation of sound from the speaker through the microphone.

As audio systems become increasingly complex, audio systems continue to support an increasingly wide range of frequencies, which support the use of ultrasonic signals in so-called ultrasonic audio systems. Ultrasonic audio systems add ultrasonic signals, which are signals that have frequencies outside the audible frequency range, to audible audio signals. The ultrasonic signals may be used to, among other things, detect physical characteristics of objects or environments. In operation, the programmable circuitry encodes the ultrasonic signals at frequencies outside of the audible frequency range onto the digital audible audio signal. The programmable circuitry uses a relatively high-speed connection to provide the combined ultrasonic/audio signal to the audio amplifier circuitry. In such a system, the echo reference signal of the audio amplifier circuitry includes both the audible and ultrasonic portions of the digital audio signal. The audio amplifier circuitry produces an output signal having both the audible signal and the ultrasonic signal based on the combined digital signal. The speaker produces the audible and ultrasonic signals responsive to the analog signal from the audio amplifier circuitry. The microphone captures the ultrasonic signals after the ultrasonic signals reflect off portions of the environment. The programmable circuitry determines physical characteristics of the environment responsive to the received ultrasonic signals from the microphone.

The range of frequencies considered to be ultrasonic is greater than the range of audible frequencies. For example, audible frequencies are between twenty and twenty thousand hertz (Hz), while ultrasonic signals may have frequencies between twenty-four thousand and forty thousand hertz (Hz). For an audio system to support ultrasonic signal generation, the programmable circuitry needs to include additional circuitry to generate the relatively higher frequency digital ultrasonic signal. Also, transmitting the digital audible and ultrasonic audio data from the programmable circuitry to the audio amplifier circuitry increases the data rate of the interface between the programmable circuitry and the audio amplifier circuitry. Such additional operations by the programmable circuitry to produce and encode ultrasonic signals onto audible audio signals increase power consumption, system complexity, etc.

Examples described herein include methods and apparatus to structure audio amplifiers for ultrasonic signal generation. In the described examples, the audio amplifier circuitry includes a first data interface, audio signal processing circuitry, a second data interface, memory circuitry, ultrasonic chirp generator circuitry, combination circuitry, and an audio channel. The first data interface couples an audio source, such as programmable circuitry, to the audio signal processing circuitry. The first data interface supports an exchange of data from the audio source to the audio signal processing circuitry using a first communication protocol and a data rate. In example operations, the audio source supplies a digital audible audio signal to the audio signal processing circuitry using the first data interface. Advantageously, using the first data interface for audible audio signals decreases the data rate of the first data interface. The audio signal processing circuitry conditions the digital audible audio signal. The audio signal processing circuitry supplies the conditioned digital audible audio signal to the audio source as the echo reference signal. Advantageously, using the echo reference signal to provide the audible portions of the audio signal to the programable circuitry reduces complexity by not needing to have ultrasonic frequencies removed.

In such described examples, the second data interface supports an exchange of data from a data source, such as the audio source or other host system, to the memory circuitry using a second communication protocol. In example operation, the data source supplies values representing characteristics of an ultrasonic signal to the memory circuitry using the second communication protocol. The memory circuitry stores the characteristics of the ultrasonic signal. The ultrasonic chirp generator circuitry generates a digital ultrasonic signal responsive to a chirp enable value being set in the memory circuitry. In example operations, the data source triggers ultrasonic signal generation by using the second data interface to set the chirp enable value. In such example operations, the values of the memory circuitry structure the ultrasonic chirp generator circuitry to generate a corresponding ultrasonic signal. The combination circuitry combines the conditioned digital audible signal and the ultrasonic signal to produce an audio signal having both audible and ultrasonic signals. The audio channel produces an analog audio signal responsive to the combined audio signal from the combination circuitry.

Advantageously, using the first data interface for digital audible audio signals reduces the data rate needed to support ultrasonic signal generation. Advantageously, supplying the conditioned digital audible audio signal as the echo reference signal reduces the complexity in filtering the audible signals from signals received by the microphone. Advantageously, the ultrasonic chirp generator circuitry reduces the complexity of the audio source by generating ultrasonic signals using values in the memory circuitry. Advantageously, the second data interface and the memory circuitry allow the audio source to structure the ultrasonic signals for specific operations. Advantageously, the ultrasonic chirp generator circuitry reduces the complexity of supporting ultrasonic detection.

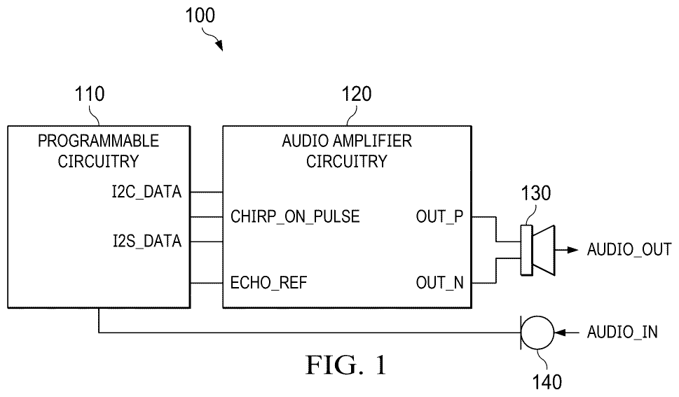

FIG. 1 is a block diagram of an example audio system 100. The example audio system 100 of FIG. 1 includes example programmable circuitry 110, example audio amplifier circuitry 120, an example speaker 130, and an example microphone 140. The audio system 100 of FIG. 1 has an input (AUDIO_IN) and an output (AUDIO_OUT). The input of the audio system 100 is an electromechanical input, which receives both audible and ultrasonic audio signals. The output of the audio system 100 is an electromechanical output, which produces both audible and ultrasonic audio signals. In the example of FIG. 1, the input of the audio system 100 is structured to receive reflections of the audio signals from the output of the audio system 100.

The programmable circuitry 110 has a first terminal, a second terminal, a third terminal, a fourth terminal, and a fifth terminal. The first, second, third, and fourth terminals of the programmable circuitry 110 are coupled to the audio amplifier circuitry 120. The fifth terminal of the programmable circuitry 110 is coupled to the microphone 140. In some examples, the programmable circuitry 110 is structured as an audio source, which supplies first and second data signals (I2S_DATA, I2C_DATA) to the audio amplifier circuitry 120. Also, the programmable circuitry 110 is structured as an audio processing system, which receives an echo reference signal (ECHO_REF) and a chirp on pulse signal (CHIRP_ON_PULSE) from the audio amplifier circuitry 120. Example operations of the programmable circuitry 110 to implement ultrasonic detection are further described below.

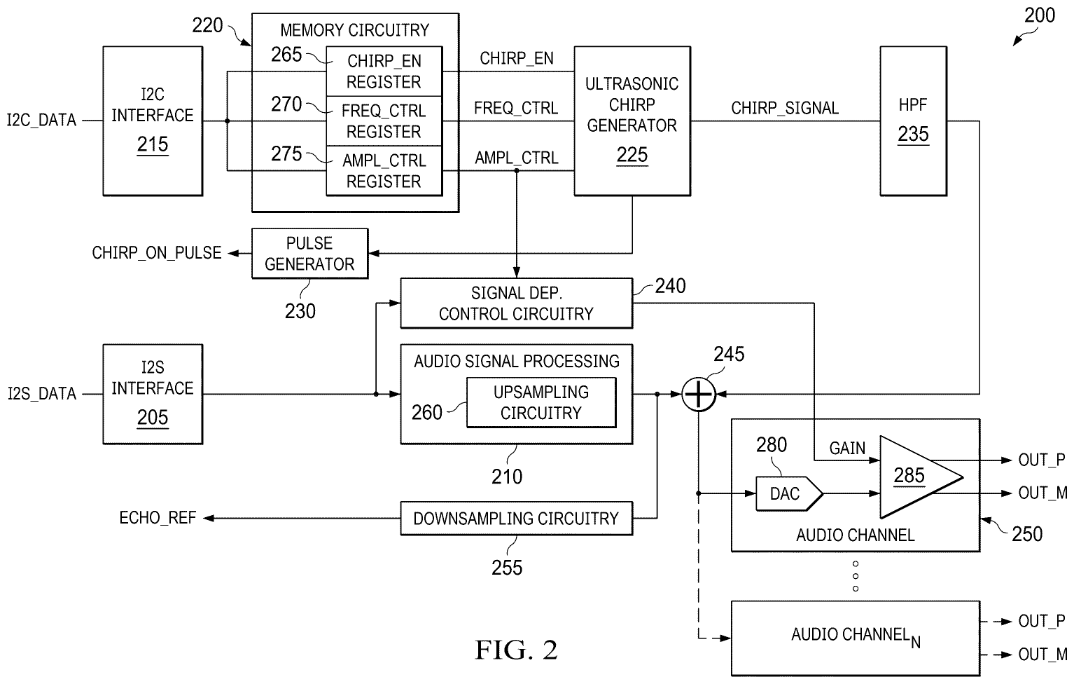

The audio amplifier circuitry 120 has a first terminal, a second terminal, a third terminal, a fourth terminal, a fifth terminal, and a sixth terminal. The first, second, third, and fourth terminals of the audio amplifier circuitry 120 are coupled to the programmable circuitry 110. The fifth and sixth terminals of the audio amplifier circuitry 120 are coupled to the speaker 130. An example of the audio amplifier circuitry 120 is further illustrated and described in connection with FIG. 2.

The speaker 130 has a first terminal and a second terminal. The first and second terminals of the speaker 130 are coupled to the audio amplifier circuitry 120. The speaker 130 is structured to be coupled to the output of the audio system 100, which provides both audible and ultrasonic signals.

The microphone 140 has a terminal coupled to the programmable circuitry 110. The microphone 140 is structured to be coupled to the input of the audio system 100, which receives both audible and ultrasonic signals.

In example operations, the programmable circuitry 110 drives an inter-IC-sound (I2S) data signal (I2S_DATA) to supply audible audio data to the audio amplifier circuitry 120. Alternatively, the programmable circuitry 110 may use a different interface to supply audible audio data to the audio amplifier circuitry 120, such as a time division multiplexing (TDM) interface, Soundwire interface, etc. The audio amplifier circuitry 120 conditions the audible audio data and provides the conditioned audible audio data as an echo reference signal (ECHO_REF). The programmable circuitry 110 receives the echo reference signal responsive to supplying the audible audio data. The audio amplifier circuitry 120 generates plus and minus output signals (OUT_P, OUT_M) by converting the conditioned audio signal from digital to analog. The plus and minus output signals drive the speaker 130 to produce audible audio signals. In such example operations, the microphone 140 produces a received audio signal responsive to collecting audio signals surrounding the audio system 100. The programmable circuitry 110 removes the echo reference signal from the received audio signal to reduce reverberation.

In example ultrasonic detection operations, the programmable circuitry 110 drives an inter-integrated circuitry (I2C) data signal (I2C_DATA) to set ultrasonic signal characteristics in the audio amplifier circuitry 120. Alternatively, the programmable circuitry 110 may use a different interface to supply ultrasonic signal characteristics to the audio amplifier circuitry 120, such as serial peripheral interface (SPI), Soundwire interface, etc. Examples of the characteristics of the ultrasonic signal are further illustrated and described in connection with FIGS. 2, 3, 4, and 5. The programmable circuitry 110 triggers the audio amplifier circuitry 120 to produce an ultrasonic audio signal using the ultrasonic signal characteristics. The audio amplifier circuitry 120 produces a chirp on pulse (CHIRP_ON_PULSE) responsive to beginning to produce the ultrasonic signal. The audio amplifier circuitry 120 produces, filters, and combines the ultrasonic signal with the conditioned audible audio signal. The audio amplifier circuitry 120 generates the plus and minus output signals by converting the conditioned audible and ultrasonic audio signals from digital to analog. The plus and minus output signals drive the speaker 130 to produce both audible and ultrasonic audio signals.

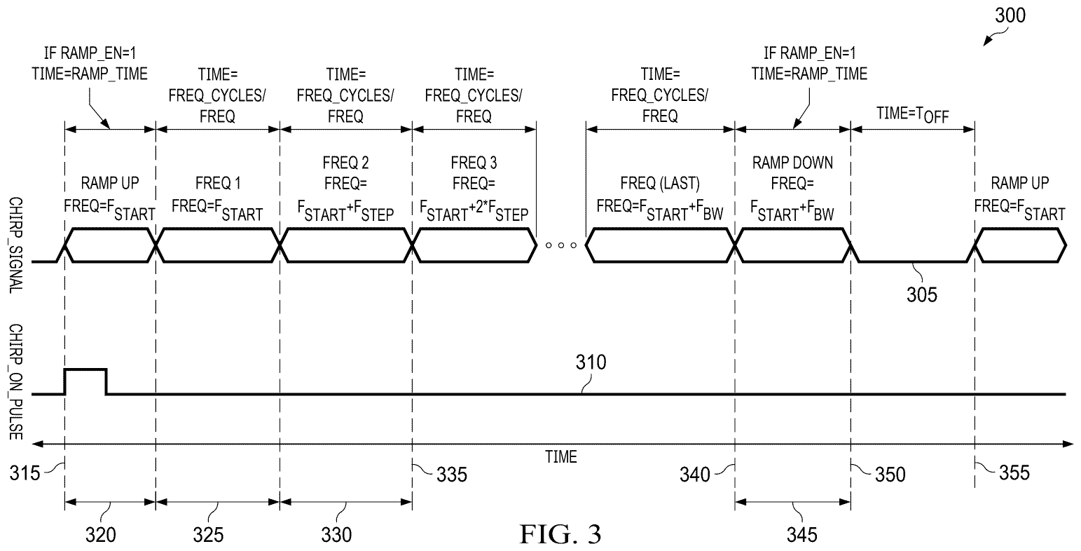

In such example operations, the microphone 140 produces a received audio signal having both reflections of the audible and ultrasonic audio signals. The programmable circuitry 110 detects physical characteristics surrounding the audio system 100 responsive to the difference between the timing of the chirp on pulse and the reception of the reflected ultrasonic signals. Advantageously, the audio amplifier circuitry 120 produces and combines ultrasonic signals with audible signals without increasing the data rates between the programmable circuitry 110 and the audio amplifier circuitry 120. Example operations of the audio amplifier circuitry 120 are further illustrated and described in connection with FIGS. 3, 4, and 5.

FIG. 2 is a block diagram of example audio amplifier circuitry 200, which is an example implementation of the audio amplifier circuitry 120 of FIG. 1. One or more portions of the audio amplifier circuitry 200 of FIG. 2 may be instantiated (e.g., creating an instance of, bring into being for any length of time, materialize, implement, etc.) by (i) an Application Specific Integrated Circuit (ASIC) or (ii) a Field Programmable Gate Array (FPGA) structured or configured in response to execution of second instructions to perform operations corresponding to the first instructions. Some or all of the audio amplifier circuitry 200 of FIG. 2 may, thus, be instantiated at the same or different times. Some or all of the audio amplifier circuitry 200 of FIG. 2 may be instantiated, for example, in one or more threads executing concurrently on hardware or in series on hardware. Moreover, in some examples, some or all of the audio amplifier circuitry 200 of FIG. 2 may be implemented by microprocessor circuitry executing instructions or FPGA circuitry performing operations to implement one or more virtual machines or containers.

In the example of FIG. 2, the audio amplifier circuitry 200 includes an inter-IC-sound (I2S) interface 205, audio signal processing circuitry 210, an inter-integrated circuitry (I2C) interface 215, memory circuitry 220, ultrasonic chirp generator circuitry 225, pulse generator circuitry 230, filter circuitry 235, signal dependent control circuitry 240, combination circuitry 245, an audio channel 250, and down sampling circuitry 255. The example audio signal processing circuitry 210 of FIG. 2 includes example upsampling circuitry 260. The example memory circuitry 220 of FIG. 2 includes an example chirp enable register 265, an example frequency control register 270, and an example amplitude control register 275. The example audio channel 250 of FIG. 2 includes example digital-to-analog converter (DAC) circuitry 280 and example amplifier 285.

The audio amplifier circuitry 200 has a first input, a second input, a first output, a second output, a third output, and a fourth output. The first input of the audio amplifier circuitry 200 is structured to be coupled to the programmable circuitry 110 of FIG. 1, which supplies an I2S data signal (I2S_DATA). The second input of the audio amplifier circuitry 200 is structured to be coupled to the programmable circuitry 110, which supplies an I2C data signal (I2C_DATA). The first output of the audio amplifier circuitry 200 is structured to be coupled to the programmable circuitry 110. The first output provides an echo reference signal (ECHO_REF). The second output of the audio amplifier circuitry 200 is structured to be coupled to the programmable circuitry 110. The second output provides a chirp on pulse (CHIRP_ON_PULSE). The third and fourth outputs of the audio amplifier circuitry 200 are structured to be coupled to the speaker 130 of FIG. 1. The third and fourth outputs, respectively, provide plus and minus output signals (OUT_P, OUT_M). In some examples, the audio amplifier circuitry 200 may include any number of audio channels. In such examples, the audio amplifier circuitry 200 may include any number of instances of the audio amplifier circuitry 200.

The I2S interface 205 has a first terminal and a second terminal. The first terminal of the I2S interface 205 receives the I2S data signal (I2S_DATA). The second terminal of the I2S interface 205 is coupled to the audio signal processing circuitry 210 and the signal dependent control circuitry 240. In the example of FIG. 2, the I2S interface 205 is structured to facilitate communications between the programmable circuitry 110 and the audio amplifier circuitry 200 using I2S communication protocols. Alternatively, in some examples, the I2S interface 205 may not be illustrated or may be integrated in a connection, bus, etc.

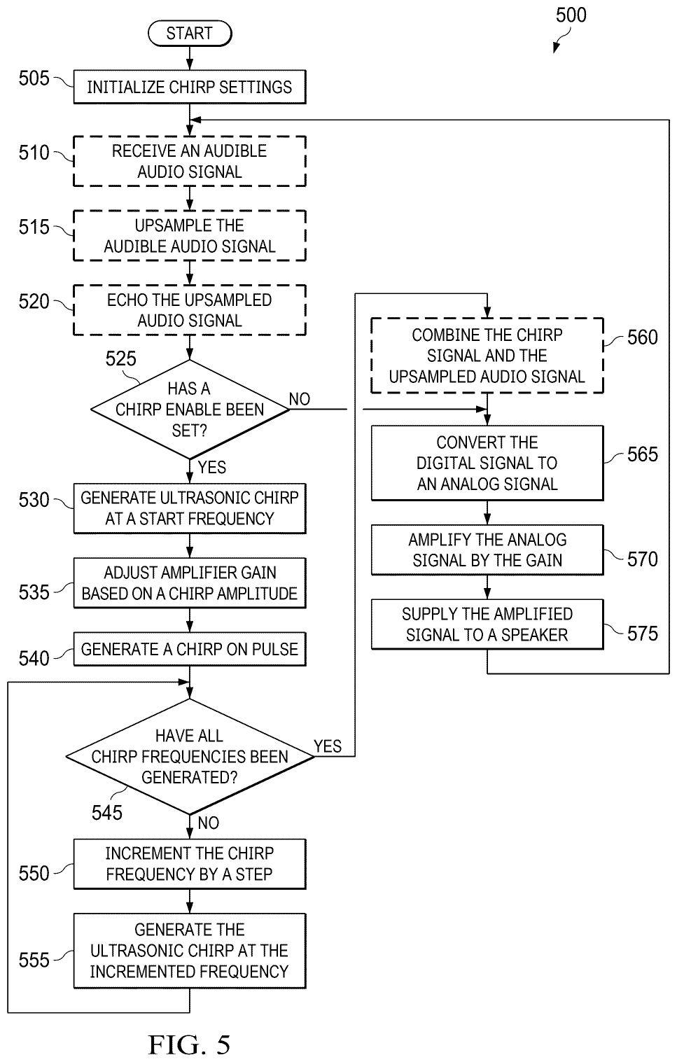

The audio signal processing circuitry 210 has a first terminal and a second terminal. The first terminal of the audio signal processing circuitry 210 is coupled to the I2S interface 205 and the signal dependent control circuitry 240. The second terminal of the audio signal processing circuitry 210 is coupled to the combination circuitry 245 and the down sampling circuitry 255. In some examples, the audio signal processing circuitry 210 is instantiated by application specific integrated circuitry or programmable circuitry executing audio signal processing instructions to perform operations such as those represented by the flowchart of FIG. 5.

The I2C interface 215 has a first terminal and a second terminal. The first terminal of the I2C interface receives the I2C data signal (I2C_DATA). The second terminal of the I2C interface 215 is coupled to the memory circuitry 220. In the example of FIG. 2, the I2C interface 215 is structured to facilitate communications between the programmable circuitry 110 and the audio amplifier circuitry 200 using I2C communication protocols. Alternatively, in some examples, the I2C interface 215 may not be illustrated or described as being integrated in a connection, bus, etc.

The memory circuitry 220 has a first terminal, a second terminal, a third terminal, and a fourth terminal. The first terminal of the memory circuitry 220 is coupled to the I2C interface 215. The second and third terminals of the memory circuitry 220 are coupled to the ultrasonic chirp generator circuitry 225. The fourth terminal of the memory circuitry 220 is coupled to the ultrasonic chirp generator circuitry 225 and the signal dependent control circuitry 240. Although in the example of FIG. 2, the memory circuitry 220 includes the registers 265, 270, 275, in other examples, the memory circuitry 220 may include any number of registers structured to control the ultrasonic chirp generator circuitry 225. In the example of FIG. 2, the memory circuitry 220 is illustrated and described as including registers. Alternatively, the memory circuitry 220 may implement another method of storage, such as a memory address-based storage.

The ultrasonic chirp generator circuitry 225 has a first terminal, a second terminal, a third terminal, a fourth terminal, and a fifth terminal. The first and second terminals of the ultrasonic chirp generator circuitry 225 are coupled to the memory circuitry 220. The third terminal of the ultrasonic chirp generator circuitry 225 is coupled to the memory circuitry 220 and the signal dependent control circuitry 240. The fourth terminal of the ultrasonic chirp generator circuitry 225 is coupled to the pulse generator circuitry 230. The fifth terminal of the ultrasonic chirp generator circuitry 225 is coupled to the filter circuitry 235. In some examples, the ultrasonic chirp generator circuitry 225 is instantiated by application specific integrated circuitry or programmable circuitry executing ultrasonic chirp generator instructions to perform operations such as those represented by the flowchart of FIG. 5.

The pulse generator circuitry 230 has a first terminal and a second terminal. The first terminal of the pulse generator circuitry 230 is coupled to the ultrasonic chirp generator circuitry 225. The second terminal of the pulse generator circuitry 230 supplies the chirp on pulse signal (CHIRP_ON_PULSE). In some examples, the pulse generator circuitry 230 is instantiated by application specific integrated circuitry or programmable circuitry executing pulse generator instructions to perform operations such as those represented by the flowchart of FIG. 5.

The filter circuitry 235 has a first terminal and a second terminal. The first terminal of the filter circuitry 235 is coupled to the ultrasonic chirp generator circuitry 225. The second terminal of the filter circuitry 235 is coupled to the combination circuitry 245. In the example of FIG. 2, the filter circuitry 235 is high-pass filter circuitry. Alternatively, the filter circuitry 235 may be an alternative type of filter, such as band pass. In some examples, the filter circuitry 235 is instantiated by application specific integrated circuitry or programmable circuitry executing filter instructions to perform operations such as those represented by the flowchart of FIG. 5.

The signal dependent control circuitry 240 has a first terminal, a second terminal, and a third terminal. The first terminal of the signal dependent control circuitry 240 is coupled to the I2S interface 205 and the audio signal processing circuitry 210. The second terminal of the signal dependent control circuitry 240 is coupled to the memory circuitry 220 and the ultrasonic chirp generator circuitry 225. The third terminal of the signal dependent control circuitry 240 (also referred to as a gain control output) is coupled to the audio channel 250. In some examples, the signal dependent control circuitry 240 has additional terminals coupled to one or more of the audio signal processing circuitry 210 or the audio channel 250. For example, the signal dependent control circuitry 240 may include additional terminals to control additional operations of the audio signal processing circuitry 210, such as voltage settings, integrated boost, power efficiency, signal optimization, etc. In some examples, the signal dependent control circuitry 240 is instantiated by programmable circuitry executing signal dependent control instructions to perform operations such as those represented by the flowchart of FIG. 5.

The combination circuitry 245 has a first terminal, a second terminal, and a third terminal. The first terminal of the combination circuitry 245 is coupled to the audio signal processing circuitry 210 and the down sampling circuitry 255. The second terminal of the combination circuitry 245 is coupled to the filter circuitry 235. The third terminal of the combination circuitry 245 is coupled to the audio channel 250. In some examples, the combination circuitry 245 is instantiated by application specific integrated circuitry or programmable circuitry executing combination instructions to perform operations such as those represented by the flowchart of FIG. 5.

The audio channel 250 has a first terminal, a second terminal, a third terminal, and a fourth terminal. The first terminal of the audio channel 250 is coupled to the signal dependent control circuitry 240. The second terminal of the audio channel 250 is coupled to the combination circuitry 245. The third and fourth terminals of the audio channel 250 are coupled to the third and fourth outputs of the audio amplifier circuitry 200, which supply the plus and minus output signals.

The down sampling circuitry 255 has an input and an output. The input of the down sampling circuitry 255 is coupled to the audio signal processing circuitry 210 and the combination circuitry 245. The output of the down sampling circuitry 255 supplies the echo reference signal (ECHO_REF).

The upsampling circuitry 260 has an input and an output. The input of the upsampling circuitry 260 is coupled to the I2S interface 205, which facilitates the supply of the I2S data signal. The output of the upsampling circuitry 260 is coupled to the combination circuitry 245 and the first output of the audio amplifier circuitry 200. In some examples, the upsampling circuitry 260 is instantiated by application specific integrated circuitry or programmable circuitry executing upsampling instructions to perform operations such as those represented by the flowchart of FIG. 5.

The chirp enable register 265 has a first terminal and a second terminal. The first terminal of the chirp enable register 265 is coupled to the I2C interface 215, the frequency control register 270, and the amplitude control register 275. The second terminal of the chirp enable register 265 is coupled to the ultrasonic chirp generator 225.

The frequency control register 270 has a first terminal and a second terminal. The first terminal of the frequency control register 270 is coupled to the I2C interface 215, the chirp enable register 265, and the amplitude control register 275. The second terminal of the frequency control register 270 is coupled to the ultrasonic chirp generator 225.

The amplitude control register 275 has a first terminal and a second terminal. The first terminal of the amplitude control register 275 is coupled to the I2C interface 215, the chirp enable register 265, and the frequency control register 270. The second terminal of the amplitude control register 275 is coupled to the ultrasonic chirp generator circuitry 225 and the signal dependent control circuitry 240.

The DAC circuitry 280 has an input and an output. The input of the DAC circuitry 280 is coupled to the combination circuitry 245. The output of the DAC circuitry 280 is coupled to the amplifier 285.

The amplifier 285 has a first input, a gain control input, a first output, and a second output. The first input of the amplifier 285 is coupled to the DAC circuitry 280. The gain control input of the amplifier 285 is coupled to the signal dependent control circuitry 240. The first output of the amplifier 285 supplies the plus output signal (OUT_P). The second output of the amplifier 285 supplies the minus output signal (OUT_M).

FIG. 3 is a timing diagram 300 of example operations of the ultrasonic chirp generator circuitry 225 of FIG. 2 or more generally the audio amplifier circuitry 120, 200 of FIGS. 1 and 2. The example timing diagram 300 of FIG. 3 includes a digital chirp signal 305 (CHIRP_SIGNAL) and an example chirp on signal 310 (CHIRP_ON_PULSE). The digital chirp signal 305 illustrates an example ultrasonic chirp of the ultrasonic chirp generator circuitry 225. An ultrasonic chirp is a form of audio signal having a varying frequency, which sweeps across a range of ultra sonic frequencies. Advantageously, varying the frequency of the ultrasonic signal provides further depth information during ultrasonic detection.

In the example of FIG. 2, the chirp enable register 265 of FIG. 2, the frequency control register 270 of FIG. 2, and the amplitude control register 275 of FIG. 2 structure the ultrasonic chirp generator circuitry 225 to produce an ultrasonic chirp having specific characteristics. In some examples, the frequency control register 270 provides frequency control values, such as a start frequency (F_{START}), a step frequency (F_{STEP}), and a frequency sweep bandwidth (F_{BW}). The start frequency specifies the lowest frequency of the digital chirp signal 305. The step frequency specifies the rate of change between frequencies of the digital chirp signal 305. The frequency sweep bandwidth specifies the total range of the frequency sweep of a chirp of the digital chirp signal 305. The amplitude control register 275 provides an amplitude control value (AMPL_CNTRL), which sets the amplitude of chirps from the ultrasonic chirp generator circuitry 225. The chirp enable register 265 provides a chirp enable value (CHIRP_EN), which triggers generation of ultrasonic signals by the ultrasonic chirp generator circuitry 225.

The chirp on signal 310 illustrates an example output of the pulse generator circuitry 230 of FIG. 2. In some examples, the chirp on signal 310 is illustrated or described as an interrupt. In operation, the pulse generator circuitry 230 aligns the generation of the chirp on signal 310 with the supply of the plus and minus output signals (OUT_P, OUT_M) by the audio channel 250. In some examples, the pulse generator circuitry 230 may delay the generation of the chirp on signal 310 to allow signals to propagate from the ultrasonic chirp generator circuitry 225 to the output of the audio amplifier circuitry 200. Advantageously, the chirp on signal 310 is aligned to have a pulse at the beginning of an ultrasonic chirp on the plus and minus output signals (OUT_P, OUT_M). Advantageously, the chirp on signal 310 allows the programmable circuitry 110 of FIG. 1 to accurately determine the time of transmission of the ultrasonic signals of the digital chirp signal 305. Advantageously, the chirp on signal 310 increases the accuracy of ultrasonic measurements by providing an accurate timing of the transmission of chirp signals.

Prior to a first time 315, the I2C interface 215 allows external circuitry, such as the programmable circuitry 110, to set the values of the chirp enable register 265, the frequency control register 270, and the amplitude control register 275. In some examples, the I2C interface 215 facilitates setting the frequency control values of the frequency control register 270 and the amplitude control value of the amplitude control register 275 prior to setting the chirp enable value of the chirp enable register 265. In such examples, setting the chirp enable value triggers the ultrasonic chirp generator circuitry 225 to generate an ultrasonic chirp using the values of the frequency control register 270 and the amplitude control register 275. In some example operations, the ultrasonic chirp generator circuitry 225 delays the generation of the ultrasonic chirp from the time at which the chirp enable value is set responsive to structuring for the frequency control values and the amplitude control value.

The example operations of the timing diagram 300 begin at the first time 315 at which the ultrasonic chirp generator circuitry 225 begins a ramp up duration 320. At the first time 315, the pulse generator circuitry 230 sets the chirp on pulse signal 310 responsive to the ultrasonic chirp generator circuitry 225 beginning the ramp up duration 320. In example operations, the rising edge of the chirp on pulse signal 310 at the first time 315 is aligned with the beginning of the ramp up duration 320. Advantageously, aligning the chirp on pulse signal 310 and the beginning of ultrasonic chirp generation allows the programmable circuitry 110 to accurately determine a timing of the start of ultrasonic signal generation. In some examples, the memory circuitry 220 of FIG. 2 may include a ramp control register, which stores a ramp duration value. In such examples, the ramp control register sets the length of the ramp up duration 320. Advantageously, ramping up the amplitude of an ultrasonic chirp signal reduces the likelihood of producing an audible pop or click.

During the ramp up duration 320, the ultrasonic chirp generator circuitry 225 increases the amplitude of the ultrasonic chirp to the amplitude control value of the amplitude control register 275. After the ramp up duration 320, the ultrasonic chirp generator circuitry 225 sets the digital chirp signal 305 to a first frequency (FREQ1) for a first frequency duration 325. In example operations, the ultrasonic chirp generator circuitry 225 sets the first frequency responsive to the start frequency value from the frequency control register 270. In some examples, the time of the first frequency duration 325 is determined by dividing the number of frequency steps (FREQ_CYCLES) by the first frequency during the first frequency duration 325.

After the first frequency duration 325, the ultrasonic chirp generator circuitry 225 increments the first frequency by the frequency step to produce a second frequency (FREQ2) for a second frequency duration 330. Similar to the time of the first frequency duration 325, the ultrasonic chirp generator circuitry 225 determines the time of the second frequency duration 330 by dividing the number of frequency steps by the second frequency.

Between a second time 335 and a third time 340, the ultrasonic chirp generator circuitry 225 continues to sweep the frequency sweep bandwidth by incrementing the frequency of the digital chirp signal 305. At the third time 340, the ultrasonic chirp generator circuitry 225 begins a ramp down duration 345. During the ramp down duration 345, the ultrasonic chirp generator circuitry 225 steadily decreases the amplitude of the digital chirp signal 305. Advantageously, ramping down the amplitude of an ultrasonic chirp signal reduces the likelihood of producing an audible pop or click.

Between a fourth time 350 and a fifth time 355, the ultrasonic chirp generator circuitry 225 is in an off state. In some examples, the duration between the fourth time 350 and the fifth time 355 is referred to as a chirp off period (CHIRP_TOFF). At the fifth time 355, the ultrasonic chirp generator circuitry 225 begins to ramp up the digital chirp signal 305 to generate a subsequent chirp.

Advantageously, the ultrasonic chirp generator circuitry 225 uses values of the memory circuitry 220 to produce relatively complex ultrasonic chirp signals. Advantageously, the ultrasonic chirp generator circuitry 225 allows the programmable circuitry 110 to produce ultrasonic chirps using the I2C interface 215.

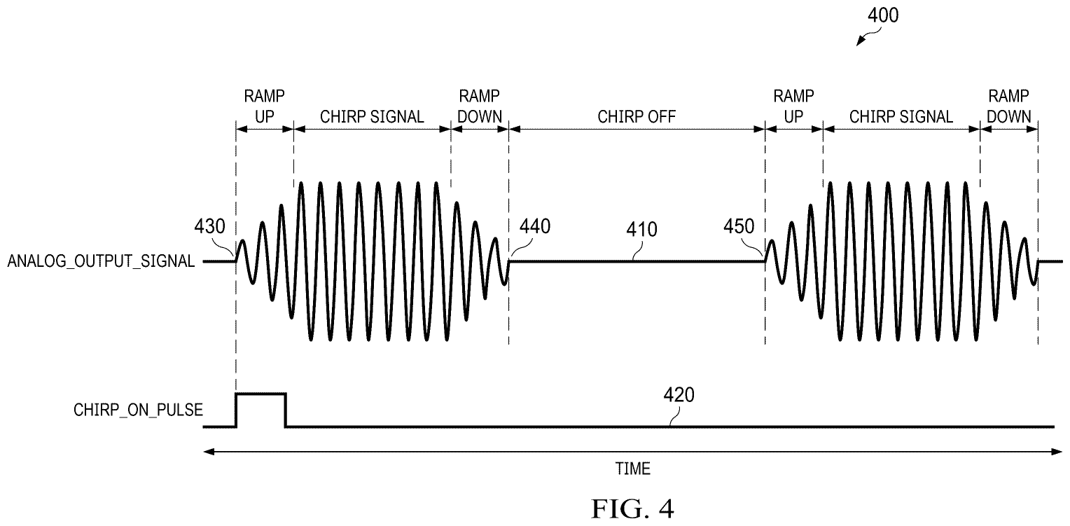

FIG. 4 is a timing diagram 400 of example operations of the ultrasonic chirp generator circuitry 225 of FIG. 2 or more generally the audio amplifier circuitry 120, 200 of FIGS. 1 and 2. The example timing diagram 400 of FIG. 4 includes an example analog output signal 410 (ANALOG_OUTPUT_SIGNAL) and an example chirp on signal 420 (CHIRP_ON_PULSE).

The analog output signal 410 illustrates the differential signal of the plus and minus output signals (OUT_P, OUT_M) of the audio amplifier circuitry 120, 200. In example operations, the DAC circuitry 280 of FIG. 2 converts the digital chirp signal 305 of FIG. 3 to an analog signal, with which the amplifier 285 of FIG. 2 produces the analog output signal 410. In some examples, the signal dependent control circuitry 240 of FIG. 2 sets a gain control value of the amplifier 285 responsive to at least one of the amplitude of a signal from the I2S interface 205 of FIG. 2 or the amplitude control value of the amplitude control register 275 of FIG. 2. In such examples, the signal dependent control circuitry 240 may reduce the gain of the amplifier 285 to reduce the likelihood of saturating the analog output signal 410.

The chirp on signal 420 illustrates an example output of the pulse generator circuitry 230 of FIG. 2. In some examples, the chirp on signal 420 is illustrated or described as an interrupt. The chirp on signal 420 of FIG. 4 is another example of the chirp on signal 310 of FIG. 3.

The example operations of the timing diagram 400 begin at a first time 430, at which the ultrasonic chirp generator circuitry 225 begins to ramp up the amplitude of the digital chirp signal 305. At the first time 430, the audio channel 250 of FIG. 2 ramps up the analog output signal 410 responsive to the ramp up of the digital chirp signal 305. At the first time 430, the pulse generator circuitry 230 sets the chirp on pulse signal 420 responsive to the ultrasonic chirp generator circuitry 225 beginning ramp up operations. Advantageously, ramping up the amplitude of the analog output signal 410 reduces the likelihood of producing an audible pop or click.

Between the first time 430 and a second time 440, the ultrasonic chirp generator circuitry 225 performs the operations illustrated and described in connection between the times 315, 350 of FIG. 3. During the duration between the first time 430 and the second time 440, the ultrasonic chirp generator circuitry 225 ramps up the amplitude of the analog output signal 410, sweeps frequencies of the frequency sweep bandwidth, and ramps down the amplitude of the analog output signal 410.

Between the second time 440 and a third time 450, the ultrasonic chirp generator circuitry 225 remains in an off state, such as between the times 350, 355 of FIG. 3. At the third time 450, the ultrasonic chirp generator circuitry 225 begins to ramp up the amplitude of a subsequent ultrasonic chirp.

FIG. 5 is a flowchart representative of example machine-readable instructions or example operations 500 that may be at least one of executed, instantiated, or performed using an example implementation of the audio amplifier circuitry 120, 200 of FIGS. 1 and 2. The example operations 500 of FIG. 5 begin at Block 505, at which the I2C interface 215 of FIG. 2 initializes chirp settings. In example operations, external circuitry, such as the programmable circuitry 110, uses the I2C interface 215 to communicate with the memory circuitry 220 of FIG. 2 using I2C communication protocols. In such example operations, the external circuitry sets values of the chirp enable register 265 of FIG. 2, the frequency control register 270 of FIG. 2, and the amplitude control register 275 of FIG. 2. In some examples, the frequency control register 270 provides frequency control values, such as a start frequency (F_{START}), a step frequency (F_{STEP}), and a frequency sweep bandwidth (F_{BW}). In some such examples, each of the frequency control values may be stored by an individual register or alternative unit of memory. The start frequency specifies the lowest frequency of the digital chirp signal 305. The step frequency specifies the rate of change between frequencies of the digital chirp signal 305. The frequency sweep bandwidth specifies the total range of the frequency sweep of a chirp of the digital chirp signal 305. The amplitude control register 275 provides an amplitude control value (AMPL_CNTRL), which sets the amplitude of chirps from the ultrasonic chirp generator circuitry 225.

In some examples, the memory circuitry 220 may include one or more additional registers structured to set characteristics of ultrasonic chirps. For example, the memory circuitry 220 may include a ramp control register to set a ramp time of ultrasonic chirps. In another example, the memory circuitry 220 may include a chirp off register to set a delay between sequential ultrasonic chirps. Also, the memory circuitry may include a frequency step register, which sets the size of frequency steps. Advantageously, external circuitry, such as the programmable circuitry 110, may use I2C communication protocols to set characteristics of ultrasonic chirps. Alternatively, the audio amplifier circuitry 120, 200 may implement another method of setting characteristics of the ultrasonic signal, such as using an alternative communication protocol or scheme.

In some example operations, as illustrated in the operations 500 of FIG. 5, the audio amplifier circuitry 120, 200 produces an audio signal having both audible and ultrasonic wavelengths. In such examples, control proceeds to perform the operations of Blocks 510, 515, 520, 560. In other example operations, as illustrated by the dashed outline of Blocks 510, 515, 520, 560, the audio amplifier circuitry 120, 200 produces an audio signal having one of audible or ultrasonic wavelengths. For example, the audio amplifier circuitry 120, 200 produces ultrasonic signals without an audible signal.

The I2S interface 205 of FIG. 2 receives an audible audio signal. (Block 510). In example operations, the external circuitry, such as the programmable circuitry 110, uses the I2S interface 205 to supply an I2S data signal using I2S communication protocols. In such example operations, the I2S data signal has a data rate to support audible frequencies. For example, a data rate of forty-eight kilo samples per second (ksps) supports signals between twenty hertz (Hz) and twenty thousand hertz (Hz), which defines the range of audible frequencies. Advantageously, the ultrasonic chirp generator circuitry 225 of FIG. 2 allows the audio system 100 of FIG. 1 to support ultrasonic frequencies without increasing the speed of the I2S data signal to support ultrasonic frequencies.

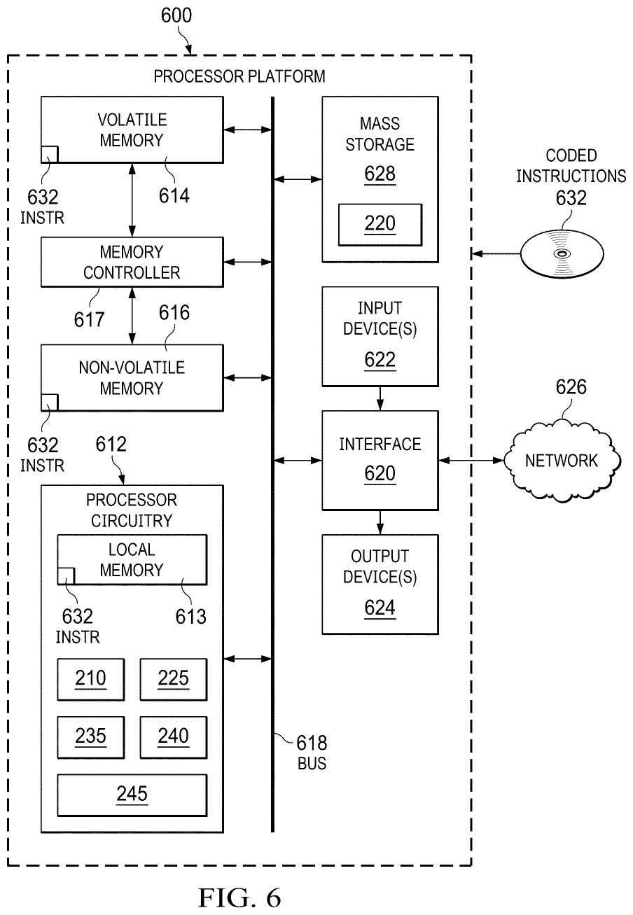

The audio signal processing circuitry 210 of FIG. 2 upsamples the audible audio signal. (Block 515). In example operation, the upsampling circuitry 260 of FIG. 6 converts the audible data of the I2S data signal from a first frequency to a second frequency, which is greater than the first frequency. For example, the upsampling circuitry 260 upsamples the forty-eight kilo samples per second (ksps), which corresponds to forty-eight kilohertz (kHz), to three-hundred and eighty-four kilo samples per second (ksps), which corresponds to three-hundred and eighty-four kilohertz (kHz). In such example operations, upsampling the audible audio signal increases the quality of the audio signal by decreasing time between samples. Advantageously, upsampling the audible audio signal produces a digital signal having enough samples to be capable of supporting ultrasonic frequencies.

The audio signal processing circuitry 210 echoes the upsampled audio signal. (Block 520). In some examples, the audio signal processing circuitry 210 supplies the upsampled audio signal as the echo reference signal (ECHO_REF). In example operations, external circuitry, such as the programmable circuitry 110, may use the echo reference signal for audio operations. For example, the programmable circuitry 110 uses the echo reference signal to cancel reverberations of the upsampled audio signal picked up by the microphone 140 of FIG. 1. Such example audio operations may be referred to as noise cancelation. Advantageously, the echo reference signal includes the audible portions of sound from the speaker 130 of FIG. 1. Advantageously, adding the ultrasonic frequencies after supplying the echo reference signal reduces complexity in removing the audio signal from received audio signals for noise cancelation.

If the audio amplifier circuitry 200 does not receive an audio signal (e.g., Blocks 510, 515, 520 are skipped) or control proceeds from Block 520, the ultrasonic chirp generator circuitry 225 of FIG. 2 determines if a chirp enable has been set. (Block 525). In some examples, the chirp enable value (CHIRP_EN) of the chirp enable register 265 triggers ultrasonic chirp generation of the ultrasonic chirp generator circuitry 225. In example operations, external circuitry triggers ultrasonic chirp generation responsive to setting the chirp enable value of the chirp enable register 265 using the I2C interface 215.

If the ultrasonic chirp generator circuitry 225 determines that the chirp enable has been set (e.g., Block 525 returns a result of YES), the ultrasonic chirp generator circuitry 225 generates an ultrasonic chirp at a start frequency. (Block 530). In some examples, the ultrasonic chirp generator circuitry 225 determines the start frequency of an ultrasonic chirp responsive to the frequency control values of the frequency control register 270. In example operations, the start frequency of the frequency control register 270 specifies the first frequency of the ultrasonic chirp. For example, the start frequency is the frequency of the digital chirp signal 305 of FIG. 3 during the first frequency duration 320 of FIG. 3. In some examples, the ultrasonic chirp generator circuitry 225 uses the first frequency during a ramp up of the amplitude of the chirp signal. For example, the ultrasonic chirp generator circuitry 225 sets the frequency of the digital chirp signal 305 to the first frequency during the ramp up duration 320 of FIG. 3. Advantageously, ramping up the amplitude of the ultrasonic chirp decreases the likelihood of producing an audible click or pop.

The signal dependent control circuitry 240 of FIG. 2 adjusts an amplifier gain based on a chirp amplitude. (Block 535). In some examples, the signal dependent control circuitry 240 monitors the amplitude of the audible data signal from the I2S interface 205 and the amplitude control value of the amplitude control register 275 of FIG. 2. In such examples, the signal dependent control circuitry 240 compares the amplitudes of the audible and ultrasonic signals to amplitude thresholds. In example operations, the signal dependent control circuitry 240 supplies an amplifier gain value to the amplifier 285 of FIG. 2 responsive to the comparison of the amplitudes. For example, the signal dependent control circuitry 240 prevents the amplifier 285 from clipping (also referred to as saturating) the audio signal responsive to decreasing the amplifier gain value of the amplifier 285. Advantageously, the signal dependent control circuitry 240 reduces the likelihood of the ultrasonic signal creating audible issues after being combined with the audible data signal.

The pulse generator circuitry 230 of FIG. 2 generates a chirp on pulse. (Block 540). In some examples, the audio system 100 uses the reflection of the ultrasonic chirps to detect characteristics of an environment, such as distance detection or gesture detection. In example operations, the pulse generator circuitry 230 aligns a rising edge of the chirp on pulse signal 310, 420 of FIGS. 3 and 4 to match the start of chirp generation. Such an alignment allows external circuitry, such as the programmable circuitry 110, to accurately time the difference between transmission of the ultrasonic chirp by the speaker 130 and the reception of the ultrasonic chirp by the microphone 140. In some examples, the pulse generator circuitry 230 includes synchronization circuitry, which directly aligns the start of chirp generation with the generation of the plus and minus output signals (OUT_P, OUT_M).

The ultrasonic chirp generator circuitry 225 determines if all chirp frequencies have been generated. (Block 545). In some examples, an ultrasonic chirp includes a sweep across a range of frequencies, which is defined by the start frequency and the frequency sweep bandwidth (F_{BW}). In such examples, the ultrasonic chirp generator circuitry 225 increments the previous frequency by the frequency step until the chirp frequency is equal to the start frequency plus the frequency sweep bandwidth. In example operations, the frequency control register 270 specifies the start frequency, the frequency step, and the frequency sweep bandwidth.

If the ultrasonic chirp generator circuitry 225 determines that not all chirp frequencies have been generated (e.g., Block 545 returns a result of NO), the ultrasonic chirp generator circuitry 225 increments the chirp frequency by a step. (Block 550). In some examples, the ultrasonic chirp generator circuitry 225 continues a frequency sweep of an ultrasonic chirp by incrementing the previous frequency by the frequency step.

The ultrasonic chirp generator circuitry 225 generates the ultrasonic chirp at the incremented frequency. (Block 555). In example operations, the ultrasonic chirp generator circuitry 225 generates the ultrasonic chirp using the determined frequency for a duration of time. In some examples, the ultrasonic chirp generator circuitry 225 determines the duration of the determined frequency by dividing the number of frequency steps (FREQ_CYCLES) by the determined frequency. In such example operations, the filter circuitry 235 of FIG. 2 is a high-pass filter, which reduces signals having frequencies less than the range ultrasonic frequencies.

If the ultrasonic chirp generator circuitry 225 determines that all chirp frequencies have been generated (e.g., Block 545 returns a result of YES), the combination circuitry 245 of FIG. 2 combines the chirp signal and the upsampled audio signal. (Block 560). In example operations, the combination circuitry 245 is addition circuitry, which adds the upsampled audio signal from the audio signal processing circuitry 210 and the ultrasonic chirp from the filter circuitry 235.

If the ultrasonic chirp generator circuitry 225 determines that the chirp enable is not set (e.g., Block 525 returns a result of NO) or control proceeds from Block 560, the DAC circuitry 280 of FIG. 2 converts the digital signal to an analog signal. (Block 565). In example operations, the DAC circuitry 280 converts the signals from the combination circuitry 245 to produce an analog audio signal. In some examples, the DAC circuitry 280 converts a combination of both audible and ultrasonic portions of the digital signal to produce an analog signal having both audible and ultrasonic frequencies. In other examples, the DAC circuitry 280 converts a digital signal having only one of the audible or ultrasonic portions to produce an analog signal having only one of audible or ultrasonic frequencies.

The amplifier 285 of FIG. 2 amplifies the analog signal by the gain. (Block 570). In example operations, the amplifier 285 amplifies the analog signal at the output of the DAC circuitry 280 by a gain, which is set by the signal dependent control circuitry 240. In some examples, the gain reduces the amplitudes of the analog signal to reduce clipping at the output of the amplifier 285.

The audio channel 250 of FIG. 2 supplies the amplifier signal to a speaker. (Block 575). In example operations, the speaker 130 produces audible and ultrasonic signals responsive to the plus and minus output signals at the output of the audio channel 250. Control proceeds to Block 510.

Example methods are described with reference to the flowchart illustrated in FIG. 5. However, many other methods of implementing the audio amplifier circuitry 120, 200 of FIGS. 1 and 2 may also be used in this description. For example, the order of execution of the blocks may be changed, or some of the blocks described may be changed, eliminated, or combined. Similarly, additional operations may be included in the manufacturing process before, in between, or after the blocks shown in the illustrated examples.

FIG. 6 is a block diagram of an example programmable circuitry platform 600 structured to one or a combination of execute or instantiate one or more of the example machine-readable instructions or the example operations of FIGS. 3, 4, and 5 to implement the audio amplifier circuitry 120, 200 of FIGS. 1 and 2. The programmable circuitry platform 600 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a personal video recorder, a headset (e.g., an augmented reality (AR) headset, a virtual reality (VR) headset, etc.) or other wearable device, or any other type of computing or electronic device.

The programmable circuitry platform 600 of the illustrated example includes programmable circuitry 612. The programmable circuitry 612 of the illustrated example is hardware. For example, the programmable circuitry 612 can be implemented by one or more integrated circuits, logic circuits, FPGAs, microprocessors, CPUs, GPUs, DSPs, or microcontrollers from any desired family or manufacturer. The programmable circuitry 612 may be implemented by one or more semiconductor based (e.g., silicon based) devices. In this example, the programmable circuitry 612 implements the audio signal processing circuitry 210 of FIG. 2, the ultrasonic chirp generator circuitry 225 of FIG. 2, the filter circuitry 235 of FIG. 2, the signal dependent control circuitry 240 of FIG. 2, and the combination circuitry 245 of FIG. 2.

The programmable circuitry 612 of the illustrated example includes a local memory 613 (e.g., a cache, registers, etc.). The programmable circuitry 612 of the illustrated example is in communication with main memory 614, 616, which includes a volatile memory 614 and a non-volatile memory 616, by a bus 618. The volatile memory 614 may be implemented by one or more Synchronous Dynamic Random Access Memory (SDRAM), Dynamic Random Access Memory (DRAM), RAMBUS® Dynamic Random Access Memory (RDRAM®), or any other type of RAM device. The non-volatile memory 616 may be implemented by one or a combination of flash memory or any other desired type of memory device. Access to the main memory 614, 616 of the illustrated example is controlled by a memory controller 617. In some examples, the memory controller 617 may be implemented by one or more integrated circuits, logic circuits, microcontrollers from any desired family or manufacturer, or any other type of circuitry to manage the flow of data going to and from the main memory 614, 616.

The programmable circuitry platform 600 of the illustrated example also includes interface circuitry 620. The interface circuitry 620 may be implemented by hardware in according to any type of interface standard, such as an Ethernet interface, a universal serial bus (USB) interface, a Bluetooth® interface, a near field communication (NFC) interface, a Peripheral Component Interconnect (PCI) interface, or a Peripheral Component Interconnect Express (PCIe) interface.

In the illustrated example, one or more input devices 622 are connected to the interface circuitry 620. The input device(s) 622 permit(s) a user (e.g., a human user, a machine user, etc.) to enter one of or a combination of data or commands into the programmable circuitry 612. The input device(s) 622 can be implemented by, for example, one of or a combination of an audio sensor, a microphone, a camera (still or video), or a voice recognition system.

One or more output devices 624 are also connected to the interface circuitry 620 of the illustrated example. The output device(s) 624 can be implemented, for example, by one of or a combination of display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, or speaker. The interface circuitry 620 of the illustrated example, thus, includes one of or a combination of a graphics driver card, a graphics driver chip, or graphics processor circuitry such as a GPU.

The interface circuitry 620 of the illustrated example also includes a communication device such as one of or a combination of a transmitter, a receiver, a transceiver, a modem, a residential gateway, a wireless access point, or a network interface to facilitate exchange of data with external machines (e.g., computing devices of any kind) by a network 626. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 600 of the illustrated example also includes one or more mass storage discs or devices 628 to store one or more of firmware, software, or data. Examples of such mass storage discs or devices 628 include one or more magnetic storage devices (e.g., floppy disk, drives, HDDs, etc.), optical storage devices (e.g., Blu-ray disks, CDs, DVDs, etc.), RAID systems, or solid-state storage discs or devices such as flash memory devices and SSDs.

The machine-readable instructions 632, which may be implemented by the machine-readable instructions of FIGS. 3, 4, and 5, may be stored in one of or a combination of the mass storage device 628, in the volatile memory 614, in the non-volatile memory 616, or on at least one non-transitory computer readable storage medium such as a CD or DVD which may be removable.

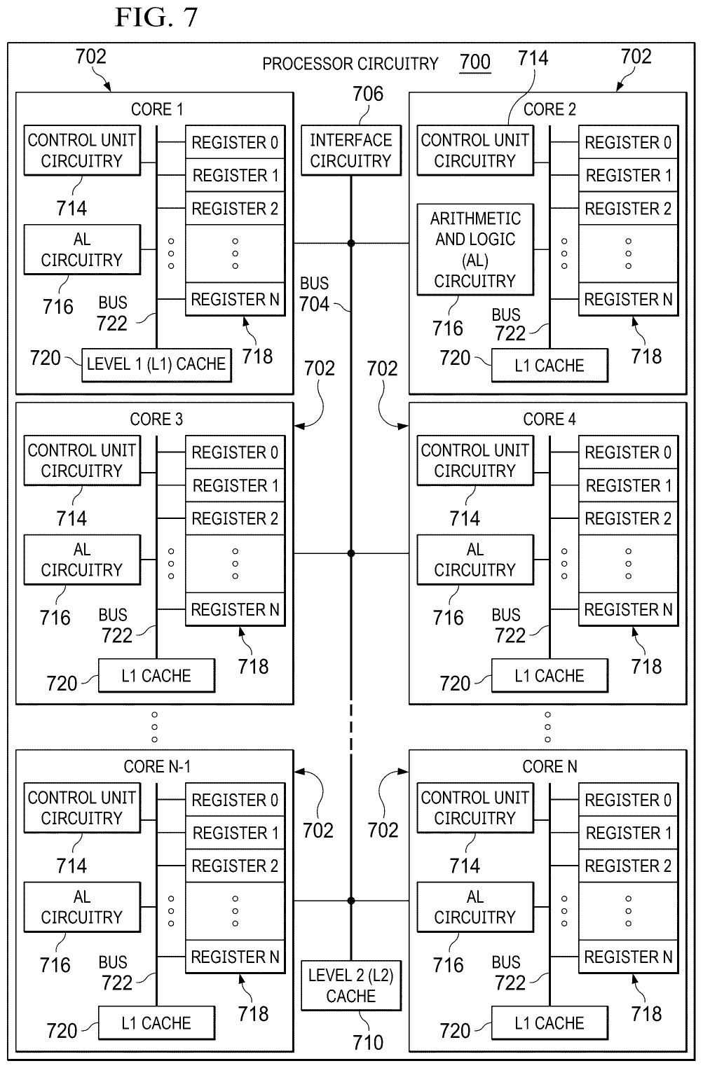

FIG. 7 is a block diagram of an example implementation of the programmable circuitry 612 of FIG. 6. In this example, the programmable circuitry 612 of FIG. 6 is implemented by a microprocessor 700. For example, the microprocessor 700 may be a general-purpose microprocessor (e.g., general-purpose microprocessor circuitry). The microprocessor 700 executes some or all of the machine-readable instructions of the timing diagrams or flowchart of FIGS. 3, 4, and 5 to effectively instantiate the circuitry of FIG. 2 as logic circuits to perform operations corresponding to those machine-readable instructions. In some such examples, the circuitry of FIGS. 1 and 2 is instantiated by the hardware circuits of the microprocessor 700 in combination with the machine-readable instructions. For example, the microprocessor 700 may be implemented by multi-core hardware circuitry such as a CPU, a DSP, a GPU, an XPU, etc. Although it may include any number of example cores 702 (e.g., 1 core), the microprocessor 700 of this example is a multi-core semiconductor device including N cores. The cores 702 of the microprocessor 700 may operate independently or may cooperate to execute machine-readable instructions. For example, machine code corresponding to a firmware program, an embedded software program, or a software program may be executed by one of the cores 702 or may be executed by multiple ones of the cores 702 at the same or different times. In some examples, the machine code corresponding to the firmware program, the embedded software program, or the software program is split into threads and executed in parallel by two or more of the cores 702. The software program may correspond to a portion or all of the machine-readable instructions or operations represented by the timing diagrams or flowchart of FIGS. 3, 4, and 5.

The cores 702 may communicate by a first example bus 704. In some examples, the first bus 704 may be implemented by a communication bus to effectuate communication associated with one(s) of the cores 702. For example, the first bus 704 may be implemented by at least one of an Inter-Integrated Circuit (I2C) bus, a Serial Peripheral Interface (SPI) bus, a PCI bus, or a PCIe bus. Also or alternatively, the first bus 704 may be implemented by any other type of computing or electrical bus. The cores 702 may obtain data, instructions, and signals from one or more external devices by example interface circuitry 706. The cores 702 may output data, instructions, and signals to the one or more external devices by the interface circuitry 706. Although the cores 702 of this example include example local memory 720 (e.g., Level 1 (L1) cache that may be split into an L1 data cache and an L1 instruction cache), the microprocessor 700 also includes example shared memory 710 that may be shared by the cores (e.g., Level 2 (L2 cache)) for high-speed access to data and instructions. Data and instructions may be transferred (e.g., shared) by one of or a combination of writing to or reading from the shared memory 710. The local memory 720 of each of the cores 702 and the shared memory 710 may be part of a hierarchy of storage devices including multiple levels of cache memory and the main memory (e.g., the main memory 614, 616 of FIG. 6). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 702 may be referred to as a CPU, DSP, GPU, etc., or any other type of hardware circuitry. Each core 702 includes control unit circuitry 714, arithmetic and logic (AL) circuitry (sometimes referred to as an ALU) 716, a plurality of registers 718, the local memory 720, and a second example bus 722. Other structures may be present. For example, each core 702 may include vector unit circuitry, single instruction multiple data (SIMD) unit circuitry, load/store unit (LSU) circuitry, branch/jump unit circuitry, floating-point unit (FPU) circuitry, etc. The control unit circuitry 714 includes semiconductor-based circuits structured to control (e.g., coordinate) data movement within the corresponding core 702. The AL circuitry 716 includes semiconductor-based circuits structured to perform one or more mathematic or logic operations on the data within the corresponding core 702. The AL circuitry 716 of some examples performs integer-based operations. In other examples, the AL circuitry 716 also performs floating-point operations. In yet other examples, the AL circuitry 716 may include first AL circuitry that performs integer-based operations and second AL circuitry that performs floating-point operations. In some examples, the AL circuitry 716 may be referred to as an Arithmetic Logic Unit (ALU).

The registers 718 are semiconductor-based structures to store data and instructions such as results of one or more of the operations performed by the AL circuitry 716 of the corresponding core 702. For example, the registers 718 may include vector register(s), SIMD register(s), general-purpose register(s), flag register(s), segment register(s), machine-specific register(s), instruction pointer register(s), control register(s), debug register(s), memory management register(s), machine check register(s), etc. The registers 718 may be arranged in a bank as shown in FIG. 7. Alternatively, the registers 718 may be organized in any other arrangement, format, or structure, such as by being distributed throughout the core 702 to shorten access time. The second bus 722 may be implemented by at least one of an I2C bus, a SPI bus, a PCI bus, or a PCIe bus.

Each core 702 or, more generally, the microprocessor 700 may include additional or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) or other circuitry may be present. The microprocessor 700 is a semiconductor device fabricated to include many transistors interconnected to implement the structures described above in one or more integrated circuits (ICs) contained in one or more packages.

The microprocessor 700 may include or cooperate with one or more accelerators (e.g., acceleration circuitry, hardware accelerators, etc.). In some examples, accelerators are implemented by logic circuitry to perform certain tasks more quickly and efficiently than can be done by a general-purpose processor. Examples of accelerators include ASICs and FPGAs such as those discussed herein. A GPU, DSP, or other programmable device can also be an accelerator. Accelerators may be on-board the microprocessor 700, in the same chip package as the microprocessor 700, or in one or more separate packages from the microprocessor 700.

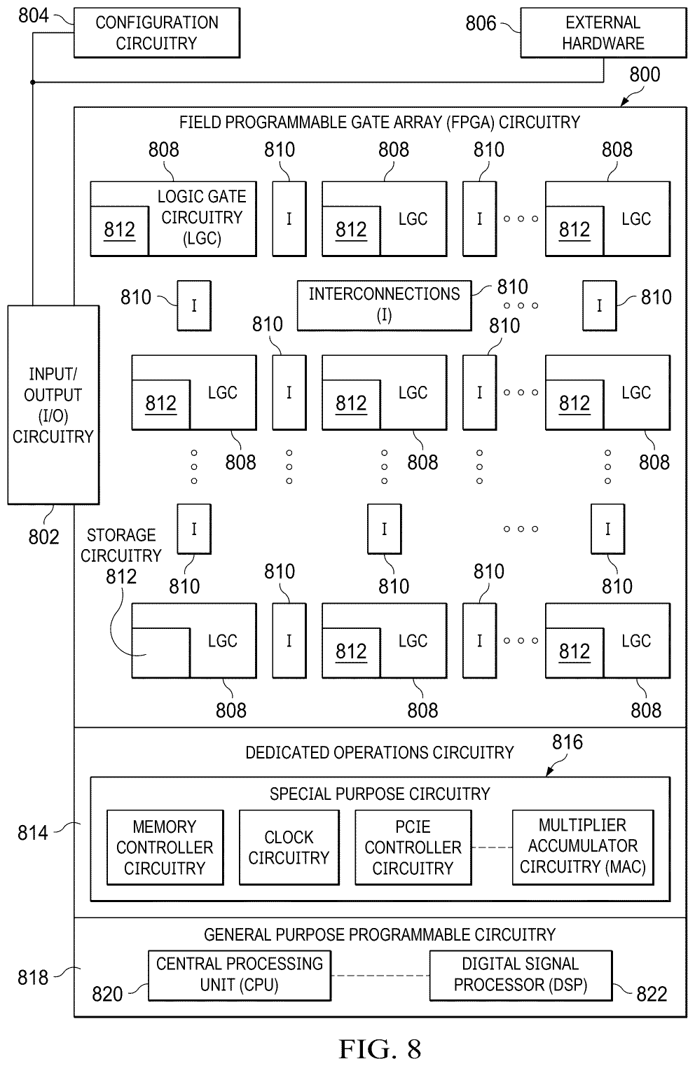

FIG. 8 is a block diagram of another example implementation of the programmable circuitry 612 of FIG. 6. In this example, the programmable circuitry 612 is implemented by FPGA circuitry 800. For example, the FPGA circuitry 800 may be implemented by an FPGA. The FPGA circuitry 800 can be used, for example, to perform operations that could otherwise be performed by the example microprocessor 700 of FIG. 7 executing corresponding machine-readable instructions. However, once configured, the FPGA circuitry 800 instantiates the operations and functions corresponding to the machine-readable instructions in hardware and, thus, can often execute the operations/functions faster than they could be performed by a general-purpose microprocessor executing the corresponding software.

More specifically, in contrast to the microprocessor 700 of FIG. 7 described above (which is a general purpose device that may be programmed to execute some or all of the machine-readable instructions represented by the timing diagrams and flowchart of FIGS. 3, 4, and 5 but whose interconnections and logic circuitry are fixed once fabricated), the FPGA circuitry 800 of the example of FIG. 8 includes interconnections and logic circuitry that may be one of or a combination of configured, structured, programmed, and interconnected in different ways after fabrication to instantiate, for example, some or all of the operations/functions corresponding to the machine-readable instructions represented by the timing diagrams and flowchart of FIGS. 3, 4, and 5. In particular, the FPGA circuitry 800 may be thought of as an array of logic gates, interconnections, and switches. The switches can be programmed to change how the logic gates are interconnected by the interconnections, effectively forming one or more dedicated logic circuits (unless and until the FPGA circuitry 800 is reprogrammed). The configured logic circuits enable the logic gates to cooperate in different ways to perform different operations on data received by input circuitry. Those operations may correspond to some or all of the instructions (e.g., the software and/or firmware) represented by the timing diagram and flowchart of FIGS. 3, 4, and 5. As such, the FPGA circuitry 800 may be at least one of configured or structured to effectively instantiate some or all of the operations/functions corresponding to the machine-readable instructions of the timing diagram and flowchart of FIGS. 3, 4, and 5 as dedicated logic circuits to perform the operations/functions corresponding to those software instructions in a dedicated manner analogous to an ASIC. Therefore, the FPGA circuitry 800 may perform the operations/functions corresponding to the some or all of the machine-readable instructions of FIGS. 3, 4, and 5 faster than the general-purpose microprocessor can execute the same.

In the example of FIG. 8, the FPGA circuitry 800 is at least one of configured or structured in response to being programmed (and/or reprogrammed one or more times) based on a binary file. In some examples, the binary file may be one of or both of compiled or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language as needed; and the code/program (e.g., the code/program in the low-level language) may be converted (e.g., by a compiler, a software application, etc.) into the binary file. In some examples, the FPGA circuitry 800 of FIG. 8 may at least one of access or load the binary file to cause the FPGA circuitry 800 of FIG. 8 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 800 of FIG. 8 to at least one of configure or structure the FPGA circuitry 800 of FIG. 8, or portion(s) thereof.

In some examples, the binary file is at least one of compiled, generated, transformed, or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is at least one of compiled, generated, or otherwise output from the uniform software platform based on the second instructions. In some examples, the FPGA circuitry 800 of FIG. 8 may at least one of access or load the binary file to cause the FPGA circuitry 800 of FIG. 8 to be at least one of configured or structured to perform the one or more operations/functions. For example, the binary file may be implemented by one of or a combination of a bit stream (e.g., one or more computer-readable bits, one or more machine-readable bits, etc.), data (e.g., computer-readable data, machine-readable data, etc.), or machine-readable instructions accessible to the FPGA circuitry 800 of FIG. 8 to at least one of configure or structure the FPGA circuitry 800 of FIG. 8, or portion(s) thereof.

The FPGA circuitry 800 of FIG. 8, includes example input/output (I/O) circuitry 802 to at least one of obtain or output data to/from at least one of example configuration circuitry 804 or external hardware 806. For example, the configuration circuitry 804 may be implemented by interface circuitry that may obtain a binary file, which may be implemented by one or more of a bit stream, data, or machine-readable instructions, to configure the FPGA circuitry 800, or portion(s) thereof. In some such examples, the configuration circuitry 804 may obtain the binary file from one of or a combination of a user, a machine (e.g., hardware circuitry (e.g., programmable or dedicated circuitry) that may implement an Artificial Intelligence/Machine Learning (AI/ML) model to generate the binary file, etc.), or any combination(s) thereof). In some examples, the external hardware 806 may be implemented by external hardware circuitry. For example, the external hardware 806 may be implemented by the microprocessor 700 of FIG. 7.

The FPGA circuitry 800 also includes an array of example logic gate circuitry 808, a plurality of example configurable interconnections 810, and example storage circuitry 812. The logic gate circuitry 808 and the configurable interconnections 810 are configurable to instantiate one or more operations/functions that may correspond to at least some of the machine-readable instructions of FIGS. 3, 4, and 5 and/or other desired operations. The logic gate circuitry 808 shown in FIG. 8 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 808 to enable configuration of one of or a combination of the electrical structures or the logic gates to form circuits to perform desired operations/functions. The logic gate circuitry 808 may include other electrical structures such as look-up tables (LUTs), registers (e.g., flip-flops or latches), multiplexers, etc.

The configurable interconnections 810 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 808 to program desired logic circuits.

The storage circuitry 812 of the illustrated example is structured to store result(s) of the one or more of the operations performed by corresponding logic gates. The storage circuitry 812 may be implemented by registers or the like. In the illustrated example, the storage circuitry 812 is distributed amongst the logic gate circuitry 808 to facilitate access and increase execution speed.

The example FPGA circuitry 800 of FIG. 8 also includes example dedicated operations circuitry 814. In this example, the dedicated operations circuitry 814 includes special purpose circuitry 816 that may be invoked to implement commonly used functions to avoid the need to program those functions in the field. Examples of such special purpose circuitry 816 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 800 may also include example general purpose programmable circuitry 818 such as an example CPU 820 or an example DSP 822. Other general purpose programmable circuitry 818 may also or alternatively be present such as a GPU, an XPU, etc., that can be programmed to perform other operations.

Although FIGS. 7 and 8 illustrate two example implementations of the programmable circuitry 612 of FIG. 6, many other approaches are contemplated. For example, FPGA circuitry may include an on-board CPU, such as one or more of the example CPU 820 of FIG. 7. Therefore, the programmable circuitry 612 of FIG. 6 may also be implemented by combining at least the example microprocessor 700 of FIG. 7 and the example FPGA circuitry 800 of FIG. 8. In some such hybrid examples, one or more cores 702 of FIG. 7 may execute a first portion of the machine-readable instructions represented by the timing diagrams and flowchart of FIGS. 3, 4, and 5 to perform first operation(s)/function(s), the FPGA circuitry 800 of FIG. 8 may be at least one of configured or structured to perform second operation(s)/function(s) corresponding to a second portion of the machine-readable instructions represented by the timing diagrams and flowchart of FIGS. 3, 4, and 5, and/or an ASIC may be at least one of configured or structured to perform third operation(s)/function(s) corresponding to a third portion of the machine-readable instructions represented by the timing diagram and flowchart of FIGS. 3, 4, and 5.

Some or all of the circuitry of FIGS. 1 and 2 may, thus, be instantiated at the same or different times. For example, same and/or different portion(s) of the microprocessor 700 of FIG. 7 may be programmed to execute portion(s) of machine-readable instructions at the same and/or different times. In some examples, same and/or different portion(s) of the FPGA circuitry 800 of FIG. 8 may be at least one of configured or structured to perform operations/functions corresponding to portion(s) of machine-readable instructions at the same and/or different times.

In some examples, some or all of the circuitry of FIGS. 1 and 2 may be instantiated, for example, in one or more threads executing concurrently and/or in series. For example, the microprocessor 700 of FIG. 7 may execute machine-readable instructions in one or more threads executing concurrently and/or in series. In some examples, the FPGA circuitry 800 of FIG. 8 may be at least one of configured or structured to carry out operations/functions concurrently and/or in series. Moreover, in some examples, some or all of the circuitry of FIGS. 1 and 2 may be implemented within one or more virtual machines or containers executing on the microprocessor 700 of FIG. 7.

In some examples, the programmable circuitry 612 of FIG. 6 may be in one or more packages. For example, at least one of the microprocessor 700 of FIG. 7 or the FPGA circuitry 800 of FIG. 8 may be in one or more packages. In some examples, an XPU may be implemented by the programmable circuitry 612 of FIG. 6, which may be in one or more packages. For example, the XPU may include a CPU (e.g., the microprocessor 700 of FIG. 7, the CPU 820 of FIG. 8, etc.) in one package, a DSP (e.g., the DSP 822 of FIG. 8) in another package, a GPU in yet another package, and an FPGA (e.g., the FPGA circuitry 800 of FIG. 8) in still yet another package.

While an example manner of implementing the audio amplifier circuitry 120, 200 of FIG. 1 is illustrated in FIGS. 1 and 2, one or more of the elements, processes, or devices illustrated in FIGS. 1 and 2 may be combined, divided, re-arranged, omitted, eliminated, or implemented in any other way. Further, the audio signal processing circuitry 210 of FIG. 2, the ultrasonic chirp generator circuitry 225 of FIG. 2, the filter circuitry 235 of FIG. 2, the signal dependent control circuitry 240 of FIG. 2, and the combination circuitry 245 of FIG. 2, or, more generally, the example audio amplifier circuitry 120, 200 of FIGS. 1 and 2, may be implemented by hardware alone or by hardware in combination with software and firmware. Thus, for example, any of the audio signal processing circuitry 210 of FIG. 2, the ultrasonic chirp generator circuitry 225 of FIG. 2, the filter circuitry 235 of FIG. 2, the signal dependent control circuitry 240 of FIG. 2, and the combination circuitry 245 of FIG. 2, or, more generally, the example audio amplifier circuitry 120, 200, could be implemented by programmable circuitry in combination with one or more machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), or field programmable logic device(s) (FPLD(s)) such as FPGAs. Further still, the example audio amplifier circuitry 120, 200 of FIGS. 1 and 2 may include one or more elements, processes, or devices in addition to, or instead of, those illustrated in FIGS. 1 and 2, or may include more than one of any or all of the illustrated elements, processes and devices.

Timing diagrams and a flowchart representative of example machine-readable instructions, which may be executed by programmable circuitry to at least one of implement or instantiate the audio amplifier circuitry 120, 200 of FIGS. 1 and 2 or representative of example operations which may be performed by programmable circuitry to at least one of implement or instantiate the audio amplifier circuitry 120, 200 of FIGS. 1 and 2, are shown in FIGS. 3, 4, and 5. The machine-readable instructions may be one or more executable programs or portion(s) of one or more executable programs for execution by programmable circuitry such as the programmable circuitry 612 shown in the example programmable circuitry platform 600 discussed below in connection with FIG. 6 and may be one or more function(s) or portion(s) of functions to be performed by the example programmable circuitry (e.g., an FPGA) discussed below in connection with FIG. 7 or 8. In some examples, the machine-readable instructions cause an operation, a task, etc., to be carried out or performed in an automated manner in the real-world. As used herein, “automated” means without human involvement.

The program may be embodied in instructions (e.g., software and/or firmware) stored on one or more non-transitory computer readable and/or machine-readable storage medium such as one of or a combination of cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), or any other storage device or storage disk. The instructions of the non-transitory computer readable and/or machine-readable medium may program or be executed by programmable circuitry located in one or more hardware devices, but the entire program or parts thereof could alternatively be executed or instantiated by one or more hardware devices other than the programmable circuitry or embodied in dedicated hardware. The machine-readable instructions may be distributed across multiple hardware devices or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 3, 4, and 5, many other methods of implementing the example audio amplifier circuitry 120, 200 may alternatively be used. For example, the order of execution of the blocks of the flowchart(s) may be changed, or some of the blocks described may be changed, eliminated, or combined. Also or alternatively, any or all of the blocks of the flow chart may be implemented by one or more hardware circuits (e.g., processor circuitry, discrete, integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations or local to one or more hardware devices (e.g., a single-core processor (e.g., a single core CPU), a multi-core processor (e.g., a multi-core CPU, an XPU, etc.)). For example, the programmable circuitry may be one of or a combination of a CPU or an FPGA located in the same package (e.g., the same integrated circuit (IC) package or in two or more separate housings), one or more processors in a single machine, multiple processors distributed across multiple servers of a server rack, multiple processors distributed across one or more server racks, etc., or any combination(s) thereof.

The machine-readable instructions described herein may be stored in one or more of a compressed format, an encrypted format, a fragmented format, a compiled format, an executable format, a packaged format, etc. Machine readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, or produce machine executable instructions. For example, the machine-readable instructions may be fragmented and stored on one or more storage devices, disks or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, or executable by a computing device or other machine. For example, the machine-readable instructions may be stored in multiple parts, which are individually compressed, encrypted, or stored on separate computing devices, wherein the parts when decrypted, decompressed, or combined form a set of one or more computer-executable or machine executable instructions that implement one or more functions or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may need to be configured (e.g., settings stored, data input, network addresses recorded, etc.) before the machine-readable instructions or the corresponding program(s) can be executed in whole or in part. Thus, machine-readable, computer readable or machine-readable media, as used herein, may include one or a combination of instructions and program(s) regardless of the particular format or state of the machine-readable instructions or program(s).

The machine-readable instructions described herein can be represented by any past, present, or future instruction language, scripting language, programming language, etc. For example, the machine-readable instructions may be represented using any of the following languages: C, C++, Java, C#, Perl, Python, JavaScript, HyperText Markup Language (HTML), Structured Query Language (SQL), Swift, etc.

As mentioned above, the example operations of FIGS. 3, 4, and 5 may be implemented using executable instructions (e.g., computer readable and/or machine-readable instructions) stored on one or more non-transitory computer readable or machine-readable media. As used herein, the terms non-transitory computer readable medium, non-transitory computer readable storage medium, non-transitory machine-readable medium, and non-transitory machine-readable storage medium are expressly defined to include any type of computer readable storage device or storage disk and to exclude propagating signals and to exclude transmission media. Examples of such non-transitory computer readable medium, non-transitory computer readable storage medium, non-transitory machine-readable medium, or non-transitory machine-readable storage medium include one or more optical storage devices, magnetic storage devices, an HDD, a flash memory, a read-only memory (ROM), a CD, a DVD, a cache, a RAM of any type, a register, or any other storage device or storage disk in which information is stored for any duration (e.g., for extended time periods, permanently, for brief instances, for temporarily buffering, for caching of the information). As used herein, the terms “non-transitory computer readable storage device” and “non-transitory machine-readable storage device” are defined to include any physical (mechanical, magnetic, electromechanical, or electrical) hardware to retain information for a time period, but to exclude propagating signals and to exclude transmission media. Examples of non-transitory computer readable storage devices or non-transitory machine-readable storage devices include one or a combination of random-access memory of any type, read only memory of any type, solid state memory, flash memory, optical discs, magnetic disks, disk drives, or redundant array of independent disks (RAID) systems. As used herein, the term “device” refers to physical structure such as one of or a combination of mechanical, electromechanical, or electrical equipment, hardware, or circuitry that may or may not be configured by computer readable instructions, machine-readable instructions, etc., or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and things, the phrase “at least one of A and B” refers to implementations including any of (1) at least one A, (2) at least one B, or (3) at least one A and at least one B. Similarly, as used herein in the context of describing structures, components, items, objects and things, the phrase “at least one of A or B” refers to implementations including any of (1) at least one A, (2) at least one B, or (3) at least one A and at least one B. As used herein in the context of describing the performance or execution of processes, instructions, actions, activities, etc., the phrase “at least one of A and B” refers to implementations including any of (1) at least one A, (2) at least one B, or (3) at least one A and at least one B. Similarly, as used herein in the context of describing the performance or execution of processes, instructions, actions, activities, etc., the phrase “at least one of A or B” refers to implementations including any of (1) at least one A, (2) at least one B, or (3) at least one A and at least one B.

As used herein, singular references (e.g., “a,” “an,” “first,” “second,” etc.) do not exclude a plurality. The term “a” or “an” object, as used herein, refers to one or more of that object. The terms “a” (or “an”), “one or more,” and “at least one” are used interchangeably herein. Furthermore, although individually listed, a plurality of means, elements, or actions may be implemented by, e.g., the same entity or object. Also, although individual features may be included in different examples or claims, these may possibly be combined, and the inclusion in different examples or claims does not imply that a combination of features is at least one of not feasible or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by at least one of the connection reference or relative movement between those elements unless otherwise indicated. As such, connection references do not necessarily infer that two elements are directly connected or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, or ordering in any way, but are merely used as at least one of labels or arbitrary names to distinguish elements for ease of understanding the described examples. In some examples, the descriptor “first” may be used to refer to an element in the detailed description, while the same element may be referred to in a claim with a different descriptor such as “second” or “third.” In such instances, such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to at least one of manufacturing tolerances or other real-world imperfections. For example, “approximately” and “about” may indicate such dimensions may be within a tolerance range of +/−10% unless otherwise specified herein.

As used herein, the phrase “in communication,” including variations thereof, encompasses one of or a combination of direct communication or indirect communication through one or more intermediary components, and does not require direct physical (e.g., wired) communication or constant communication, but rather also includes selective communication at least one of periodic intervals, scheduled intervals, aperiodic intervals, or one-time events.

As used herein, “programmable circuitry” is defined to include at least one of (i) one or more special purpose electrical circuits (e.g., an application specific circuit (ASIC)) structured to perform specific operation(s) and including one or more semiconductor-based logic devices (e.g., electrical hardware implemented by one or more transistors), or (ii) one or more general purpose semiconductor-based electrical circuits programmable with instructions to perform one or more specific functions(s) or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations or functions, Field Programmable Gate Arrays (FPGAs) that may be programmed with second instructions to at least one of configure or structure the FPGAs to instantiate one or more operations or functions corresponding to the first instructions, Graphics Processor Units (GPUs) that may execute first instructions to perform one or more operations or functions, Digital Signal Processors (DSPs) that may execute first instructions to perform one or more operations or functions, XPUs, Network Processing Units (NPUs) one or more microcontrollers that may execute first instructions to perform one or more operations or functions or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

A device that is “configured to” perform a task or function may be configured (e.g., at least one of programmed or hardwired) at a time of manufacturing by a manufacturer to at least one of perform the function or be configurable (or re-configurable) by a user after manufacturing to perform the function/or other additional or alternative functions. The configuring may be through at least one of firmware or software programming of the device, through at least one of a construction or layout of hardware components and interconnections of the device, or a combination thereof.

As used herein, the terms “terminal,” “node,” “interconnection,” “pin” and “lead” are used interchangeably. Unless specifically stated to the contrary, these terms are generally used to mean an interconnection between or a terminus of a device element, a circuit element, an integrated circuit, a device or other electronics or semiconductor component.

In the description and claims, described “circuitry” may include one or more circuits. A circuit or device that is described herein as including certain components may instead be adapted to be coupled to those components to form the described circuitry or device. For example, a structure described as including one or more semiconductor elements (such as transistors), one or more passive elements (such as one of or a combination of resistors, capacitors, or inductors), or one or more sources (such as voltage and/or current sources) may instead include only the semiconductor elements within a single physical device (e.g., at least one of a semiconductor die or integrated circuit (IC) package) and may be adapted to be coupled to at least some of the passive elements or the sources to form the described structure either at a time of manufacture or after a time of manufacture, for example, by at least one of an end-user or a third-party.

Circuits described herein are reconfigurable to include the replaced components to provide functionality at least partially similar to functionality available prior to the component replacement. Components shown as resistors, unless otherwise stated, are generally representative of any one or more elements coupled in at least one of series or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and some features illustrated as being internal to the integrated circuit may be incorporated outside of the integrated. As used herein, the term “integrated circuit” means one or more circuits that are at least one of: (i) incorporated in/over a semiconductor substrate; (ii) incorporated in a single semiconductor package; (iii) incorporated into the same module; or (iv) incorporated in/on the same printed circuit board.

Uses of the phrase “ground” in the foregoing description include at least one of a chassis ground, an Earth ground, a floating ground, a virtual ground, a digital ground, a common ground, or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

Modifications are possible in the described embodiments, and other embodiments are possible, within the scope of the claims.

What is claimed is:

1. An apparatus comprising:
audio amplifier circuitry including:
audio signal processing circuitry having an output;
a register having an output;
ultrasonic chirp generator circuitry having an input and an output, the input of the ultrasonic chirp generator circuitry coupled to the output of the register;
combination circuitry having a first input, a second input, and an output, the first input of the combination circuitry coupled to the output of the audio signal processing circuitry, the second input of the combination circuitry coupled to the ultrasonic chirp generator circuitry;
digital-to-analog converter (DAC) circuitry having an input and an output, the input of the DAC circuitry coupled to the output of the combination circuitry; and
an amplifier having an input coupled to the output of the DAC circuitry.

2. The apparatus of claim 1, wherein the register is a chirp enable register, the input of the ultrasonic chirp generator circuitry is a first input, the ultrasonic chirp generator circuitry further has a second input and a third input, and the audio amplifier circuitry further comprising:
a frequency control register having an output coupled to the second input of the ultrasonic chirp generator circuitry; and
an amplitude control register having an output coupled to the third input of the ultrasonic chirp generator circuitry.

3. The apparatus of claim 2, wherein the audio signal processing circuitry further has an input, the input of the amplifier circuitry is a first input, the amplifier circuitry further has a gain control input, and the audio amplifier circuitry further comprising signal dependent control circuitry having a first input, a second input, and a gain control output, the first input of the signal dependent control circuitry coupled to the input of the audio signal processing circuitry, the second input of the signal dependent control circuitry coupled to the third input of the ultrasonic chirp generator circuitry and the output of the amplitude control register, the gain control output of the signal dependent control circuitry coupled to the gain control input of the amplifier.

4. The apparatus of claim 2, wherein the chirp enable register further has an input, the frequency control register further has an input, and the amplitude control register further has an input, and the audio amplifier circuitry further comprising an inter-integrated circuitry (I2C) interface having an output coupled to the input of the chirp enable register, the input of the frequency control register, and the input of the amplitude control register.

5. The apparatus of claim 1, wherein the output of the ultrasonic chirp generator circuitry is a first output, the ultrasonic chirp generator circuitry further has a second output, and the audio amplifier circuitry comprising a pulse generator having an input coupled to the second output of the ultrasonic chirp generator circuitry.

6. The apparatus of claim 1, wherein the audio amplifier circuitry further comprising:
an inter-IC-sound (I2S) interface having an output; and
wherein the audio signal processing circuitry further includes upsampling circuitry having an input and an output, the input of the upsampling circuitry coupled to the output of the I2S interface, the output of the upsampling circuitry coupled to the first input of the combination circuitry.

7. The apparatus of claim 1, wherein the audio signal processing circuitry further has an input, the register further has an input, the amplifier further has an output, and the audio amplifier circuitry further comprising:
programmable circuitry having an input, a first output, and a second output, the input of the programmable circuitry coupled to the output of the audio signal processing circuitry and the first input of the combination circuitry, the first output of the programmable circuitry coupled to the input of the audio signal processing circuitry, the second output of the programmable circuitry coupled to the input of the register; and
a speaker having an input coupled to the output of the amplifier.

8. An apparatus comprising:
programmable circuitry having an output;
audio amplifier circuitry including:
audio signal processing circuitry having an input and an output, the input of the audio signal processing circuitry coupled to the output of the programmable circuitry;
ultrasonic chirp generator circuitry having an output;
combination circuitry having a first input, a second input, and an output, the first input of the combination circuitry coupled to the output of the audio signal processing circuitry, the second input of the combination circuitry coupled to the output of the ultrasonic chirp generator circuitry; and
an audio channel having an input and an output, the input of the audio channel coupled to the output of the combination circuitry; and
a speaker having an input coupled to the output of the audio channel.

9. The apparatus of claim 8, wherein the ultrasonic chirp generator circuitry further has a first input, a second input, and a third input, and the apparatus further comprising:
a chirp enable register having an output coupled to the first input of the ultrasonic chirp generator circuitry;
a frequency control register having an output coupled to the second input of the ultrasonic chirp generator circuitry; and
an amplitude control register having an output coupled to the third input of the ultrasonic chirp generator circuitry.

10. The apparatus of claim 9, wherein the input of the audio channel is a first input, the audio channel has a second input, and the apparatus further comprising signal dependent control circuitry having a first input, a second input, and an output, the first input of the signal dependent control circuitry coupled to the input of the audio signal processing circuitry, the second input of the signal dependent control circuitry coupled to the third input of the ultrasonic chirp generator circuitry and the output of the amplitude control register, the output of the signal dependent control circuitry coupled to the second input of the audio channel.

11. The apparatus of claim 9, wherein the output of the programmable circuitry is a first output, the programmable circuitry further has a second output, the chirp enable register further has an input, the frequency control register further has an input, and the amplitude control register further has an input, and the apparatus further comprising an inter-integrated circuitry (I2C) bus having an input and an output, the input of the I2C bus coupled to the second output of the programmable circuitry, the output of the I2C bus coupled to the input of the chirp enable register, the input of the frequency control register, and the input of the amplitude control register.

12. The apparatus of claim 8, wherein the output of the ultrasonic chirp generator circuitry is a first output, the ultrasonic chirp generator circuitry further has a second output, and the apparatus comprising pulse generator circuitry having an input coupled to the second output of the ultrasonic chirp generator circuitry.

13. The apparatus of claim 8, further comprising:
an inter-IC-sound (I2S) bus having an input and an output, the input of the I2S bus coupled to the output of the programmable circuitry; and
wherein the audio signal processing circuitry includes upsampling circuitry having an input and an output, the input of the upsampling circuitry coupled to the output of the I2S bus, the output of the upsampling circuitry coupled to the first input of the combination circuitry.

14. The apparatus of claim 8, wherein the audio channel includes:
digital-to-analog converter (DAC) circuitry having an input and an output, the input of the DAC circuitry coupled to the output of the combination circuitry; and
an amplifier having an input and an output, the input of the amplifier circuitry coupled to the output of the DAC circuitry, the output of the amplifier circuitry coupled to the input of the speaker.

15. An apparatus comprising:
audio amplifier circuitry including:
audio signal processing circuitry having an output;
ultrasonic chirp generator circuitry having an output, the ultrasonic chirp generator circuitry configured to generate an ultrasonic chirp signal having a plurality of frequencies, the plurality of frequencies are based on a start frequency, a step frequency, and an amplitude;
combination circuitry having a first input, a second input, and an output, the first input of the combination circuitry coupled to the output of the audio signal processing circuitry, the second input of the combination circuitry coupled to the ultrasonic chirp generator circuitry, the combination circuitry configured to combine an audible audio signal and the ultrasonic chirp signal; and
an audio channel having an input coupled to the output of the combination circuitry.

16. The apparatus of claim 15, wherein the ultrasonic chirp generator circuitry further has a first input, a second input, and a third input, the audio amplifier circuitry further including:
a chirp enable register having an output coupled to the first input of the ultrasonic chirp generator circuitry, the chirp enable register configured to trigger the ultrasonic chirp generator circuitry to generate the ultrasonic chirp signal;
a frequency control register having an output coupled to the second input of the ultrasonic chirp generator circuitry, the frequency control register configured to set the start frequency and the step frequency of the ultrasonic chirp signal; and
an amplitude control register having an output coupled to the third input of the ultrasonic chirp generator circuitry, the amplitude control register configured to set an amplitude of the ultrasonic chirp signal.

17. The apparatus of claim 16, wherein the audio signal processing circuitry further has an input, the input of the audio channel is a first input, the audio channel further has a second input, and the audio amplifier circuitry further comprising signal dependent control circuitry having a first input, a second input, and an output, the first input of the signal dependent control circuitry coupled to the input of the audio signal processing circuitry, the second input of the signal dependent control circuitry coupled to the output to the output of the amplitude control register, the output of the signal dependent control circuitry coupled to the second input of the audio channel, the signal dependent control circuitry configured to provide a signal indicating an amplifier gain value based on amplitudes of the audible audio signal and the amplitude of the ultrasonic chirp signal.

18. The apparatus of claim 16, wherein the output of the ultrasonic chirp generator circuitry is a first output, the ultrasonic chirp generator circuitry further has a second output, and the audio amplifier circuitry comprising a pulse generator circuitry having an input coupled to the second output of the ultrasonic chirp generator circuitry, the pulse generator circuitry configured to generate a chirp on pulse having a start aligned with a start of the ultrasonic chirp signal.

19. The apparatus of claim 15, wherein the ultrasonic chirp generator circuitry further has an input, the audio signal processing circuitry further has an input, and the audio amplifier circuitry further comprising:
a register having an input and an output, the output of the register coupled to the input of the ultrasonic chirp generator circuitry;
an inter-integrated circuitry (I2C) interface having an output coupled to the input of the register, the I2C interface configured to communicate using I2C communication protocols; and
an inter-IC-sound (I2S) interface having an output coupled to the input of the audio signal processing circuitry, the I2S interface configured to communicate using I2S communication protocols.

20. The apparatus of claim 15, wherein the audio signal processing circuitry is configured to upsample the audible audio signal having audible frequencies.
